(19) United States
(12) Patent Application Publication
(10) Pub. No.: US 2025/0363668 A1
(43) Pub. Date: Nov. 27, 2025

(54) SIGNAL ANALYSIS INTERACTION METHOD, APPARATUS, ELECTRONIC DEVICE AND STORAGE MEDIUM

(71) Applicant: RIGOL TECHNOLOGIES (BEIJING) , INC., Beijing (CN)

(72) Inventors: Xiaohua HE, Beijing (CN); Yue WANG, Beijing (CN)

(21) Appl. No.: 19/295,331

(22) Filed: Aug. 8, 2025

Related U.S. Application Data
(63) Continuation-in-part of application No. PCT/CN2024/097887, filed on Jun. 7, 2024.

(30) Foreign Application Priority Data
Aug. 30, 2023 (CN) 202311107692.5

(51) Int. Cl. G06T 7/90; G01R 13/02; G06F 3/04842

(52) U.S. Cl. CPC G06T 7/90; G01R 13/0227; G06F 3/04842; G06T 2200/24; G06T 2207/10024; G06T 2207/20104

(57) ABSTRACT

An embodiment of the present disclosure provides a signal analysis interaction method, a signal analysis apparatus, an electronic device, and a computer-readable storage medium. The method includes displaying a signal analysis item configuration interface in the screen; obtaining a first control operation via the signal analysis item configuration interface to determine one or more analysis items to be performed; displaying a waveform image of at least one obtained signal according to the obtained signal; displaying a selection area in response to a second control operation, where the selection area is configured to indicate an area selected through the second control operation; obtaining a parameter of a signal selected through the second control operation according to an image in the selection area; and performing the one or more analysis items to be performed according to the parameter of the signal and displaying a performing result.

### CROSS REFERENCE TO RELATED APPLICATIONS

This application is a continuation-in-part application of International Application No. PCT/CN2024/097887, filed on Jun. 7, 2024, which claims priority to Chinese patent application No. 2023111076925, filed on Aug. 30, 2023, entitled “SIGNAL ANALYSIS INTERACTION METHOD, APPARATUS, ELECTRONIC DEVICE, AND STORAGE MEDIUM”, which is hereby incorporated by reference in its entirety.

### TECHNICAL FIELD

The present disclosure relates to the technical field of signal analysis, and in particular, to a signal analysis interaction method, a signal analysis apparatus, an electronic device, and a computer-readable storage medium.

### BACKGROUND

In the technical field of electronic measurement, electronic measurement instruments such as an oscilloscope and a spectrum analyzer have been widely used. The electronic measurement instrument can transform various electrical signals such as voltage and current that are invisible to naked eyes into visible waveform curves for display, which is convenient for people to study the change process of various electrical phenomena. During the process of displaying the waveform curve of each signal through the electronic measurement instrument, test parameters of each waveform curve need to be set through the electronic measurement instrument to detect the signal quality of the electrical signal corresponding to the waveform curve.

Currently, when a signal test is performed by using such an electronic measurement instrument, a desired operation needs to be obtained through a plurality of hierarchical menus, for example, a channel, a measurement range, and a function option, etc., are set step by step from a start menu. The operation is complicated, time-consuming, and has low efficiency.

### SUMMARY

In view of this, an embodiment of the present disclosure provides a signal analysis interaction method, a signal analysis apparatus, an electronic device, and a computer-readable storage medium.

In a first aspect, an embodiment of the present disclosure provides a signal analysis interaction method applied to a signal analysis apparatus including a screen, and the method includes:
displaying a signal analysis item configuration interface in the screen;
obtaining a first control operation via the signal analysis item configuration interface to determine one or more analysis items to be performed;
displaying a waveform image of at least one obtained signal in an image display area of the screen according to the at least one obtained signal;
displaying a selection area in the image display area of the screen in response to a second control operation, where the selection area is configured to indicate an area selected through the second control operation in the image display area;
obtaining a parameter of a signal selected through the second control operation according to an image in the selection area; and
performing the one or more analysis items to be performed according to the parameter of the signal and displaying a performing result.

Combining with the first aspect of the present disclosure, in an optional implementation, the parameter of the signal includes a channel list of the signal, and
the step of obtaining a parameter of the signal selected through the second control operation according to an image in the selection area includes:
obtaining pixel colors of the image in the selection area; and
determining the channel list according to a correspondence between the pixel colors and channels of the signal.

Combining with the first aspect of the present disclosure, in an optional implementation, the step of obtaining pixel colors of the image in the selection area includes: selecting at least one column of pixels in the selection area; and determining the pixel colors of the image in the selection area according to colors of the at least one column of pixels.

Combining with the first aspect of the present disclosure, in an optional implementation, the parameter of the signal includes a first signal range and a second signal range, and the step of obtaining a parameter of the signal selected through the second control operation according to an image in the selection area includes: determining the first signal range and the second signal range, respectively, according to a horizontal range and a vertical range of the image in the selection area.

Combining with the first aspect of the present disclosure, in an optional implementation, the parameter of the signal includes a channel list of the signal, and the method comprises: determining the channel list according to the first signal range and the second signal range.

Combining with the first aspect of the present disclosure, in an optional implementation, after the step of obtaining a first control operation via the signal analysis item configuration interface to determine one or more analysis items to be performed, the method further includes: displaying a list of the analysis items to be performed.

Combining with the first aspect of the present disclosure, in an optional implementation, a waveform of the at least one obtained signal includes a time domain waveform or a frequency domain waveform,
the parameter of the signal corresponding to the time domain waveform includes a time range, an amplitude range, a channel identification, and/or signal data, and
the parameter of the signal corresponding to the frequency domain waveform includes a frequency range, signal power, a channel identification, and/or signal data.

In a second aspect, an embodiment of the present disclosure provides a signal analysis apparatus including:
a display unit, configured to display a signal analysis item configuration interface in a screen and display a waveform image of at least one obtained signal in an image display area of the screen according to the at least one obtained signal;
a control operation obtaining unit, configured to obtain a first control operation via the analysis item configuration interface to determine one or more analysis items to be performed, and obtain a second control operation, and
the display unit is further configured to display a selection area in the image display area of the screen in response to the second control operation, where the selection area is configured to indicate an area selected through the second control operation in the image display area; and
a processing unit, configured to obtain a parameter of the signal selected through the second control operation according to an image in the selection area, perform the one or more analysis items to be performed according to the parameter of the signal, and control the display unit to display a performing result.

In a third aspect, an embodiment of the present disclosure provides an electronic device including a memory and a processor, and a computer program is stored in the memory, where when executing the computer program, the processor implements steps of the signal analysis interaction method according to any of the above aspects.

In a fourth aspect, an embodiment of the present disclosure provides a computer readable storage medium, having a computer program stored thereon, where when the computer program is executed by a processor, steps of the signal analysis interaction method according to any of the above aspects are implemented.

In the signal analysis interaction method, the signal analysis apparatus, the electronic device, and the computer-readable storage medium provided in the embodiments of the present disclosure, a first control operation is obtained via the signal analysis item configuration interface to set an analysis item desired to be performed, and a second control operation is obtained to determine a selected signal waveform to be analyzed in an image display area of the screen, and thus an analysis item the user concerned can be freely configured, and the signal to be analyzed can be quickly selected. Thus, the technical problem of signal analysis traditionally realized by performing a plurality of interactions, which is complicated, time-consuming, and inefficient, can be solved, thereby improving the operational flexibility and convenience of the waveform analysis, and improving the efficiency of the signal analysis.

Additional aspects and advantages of the present disclosure will be set forth in part in the following description, and in part will be obvious from the following description, or may be learned by practice of the present disclosure.

### BRIEF DESCRIPTION OF DRAWINGS

The drawings described herein are used to provide a further understanding of the present disclosure and constitute a part of the present disclosure. The illustrative embodiments of the present disclosure and the description thereof are used to explain the present disclosure and do not constitute an improper limitation on the present disclosure. In the drawings:

FIG. 1 is a schematic flowchart illustrating a signal analysis interaction method provided in an embodiment of the present disclosure;

FIG. 2 is a schematic diagram illustrating a signal analysis item configuration interface provided in an embodiment of the present disclosure;

FIG. 3 is a schematic diagram illustrating display of an analysis item list provided in an embodiment of the present disclosure;

FIG. 4 is a first schematic diagram illustrating an image display area in an embodiment of the present disclosure;

FIG. 5 is a second schematic diagram illustrating an image display area in an embodiment of the present disclosure;

FIG. 6 is a schematic diagram illustrating waveform overlap in an embodiment of the present disclosure;

FIG. 7 is a schematic diagram illustrating display of an analysis result in an embodiment of the present disclosure;

FIG. 8 is a first schematic diagram illustrating a signal analysis apparatus provided in an embodiment of the present disclosure;

FIG. 9 is a second schematic diagram illustrating a signal analysis apparatus provided in an embodiment of the present disclosure; and

FIG. 10 is a schematic diagram illustrating an electronic device provided in an embodiment of the present disclosure.

### DETAILED DESCRIPTION

To make the technical solutions and beneficial effects of the present disclosure more obvious and understandable, the technical solutions in the embodiments of the present disclosure are clearly and completely described below by enumerating specific embodiments. Obviously, the described embodiments are only part of the embodiments of the present disclosure, not all of the embodiments. Based on the embodiments in the present disclosure, all other embodiments obtained by those ordinary skilled in the art without creative work are within the protection scope of the present disclosure.

Unless otherwise defined, technical and scientific terms used herein have the same meaning as those commonly understood by those skilled in the art to which the present disclosure belongs. The terms used in the specification of the present disclosure are only for the purpose of describing specific embodiments and are not intended to limit the present disclosure.

It can be understood that the terms “first,” “second,” or the like may be used in the present disclosure to describe various elements, but these elements are not limited by these terms. These terms are only used to distinguish one element from another element. For example, without departing from the scope of the present disclosure, the first resistor can be referred to as the second resistor, and similarly, the second resistor can be referred to as the first resistor. Both the first resistor and the second resistor are resistors, but they are not the same resistor. When a “first” one is described, it does not mean that there must be a “second” one. When a “second” one is discussed, it does not mean that there must be a first element, part, area, layer, or portion in the present disclosure. When used herein, the singular forms “a,” “an,” and “said/the” may be intended to include the plural forms as well, unless the context clearly indicates otherwise. The term “a plurality of” means two or more, unless specifically defined otherwise. It should also be understood that when the term “comprise/include” is used in the specification, it specifies the presence of the feature, but does not preclude the presence or addition of one or more other features. When used herein, the term “and/or” includes any and all combinations of the associated listed items.

It can be understood that, in the context of the present disclosure, “connection” means that there is a transmission of electrical signals or data between a connected end and the other connected end, which can be understood as “electrical connection,” “communication connection,” etc. In the context of the present disclosure, “A is directly connected to B” means that no components other than a wire are included between A and B.

A signal analysis interaction method and a signal analysis apparatus provided in the embodiment of the present disclosure can be applied to an electronic measurement instrument, such as an oscilloscope, a spectrum analyzer, a frequency meter, or the like.

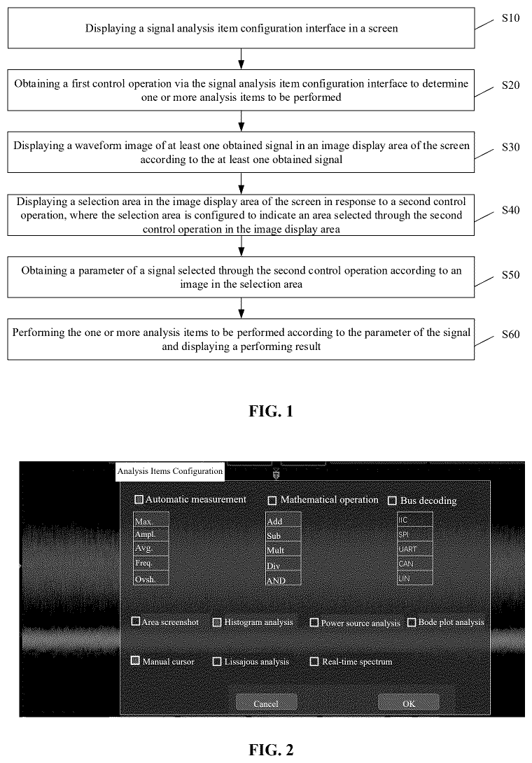

Referring to FIG. 1, a signal analysis interaction method is applied to a signal analysis apparatus including a screen, and the method includes the following steps:

S10, displaying a signal analysis item configuration interface in the screen. The signal analysis item configuration interface includes two or more analysis item selection controls. The signal analysis item configuration interface is configured to show a user analysis functions that the device can implement, thereby facilitating the user intuitively determining an item to be analyzed through visual interaction. Optionally, the signal analysis item configuration interface includes different function areas, which are obtained by dividing an area according to the analysis functions. The function area includes at least one selection control configured to obtain the user's control operation to determine the analysis item selected by the user. Optionally, the selection control includes a text input box, a button control, a checkbox control, a radio control, a drop-down selection control, a list control, etc. Optionally, the screen includes a touch screen or a non-touch screen. A manner for obtaining the user's control operation includes obtaining an analysis item corresponding to a selection control selected by the user using an input device such as a mouse, a keyboard, or a touch screen, etc.

FIG. 2 illustrates a possible signal analysis item configuration interface including a plurality of function areas, such as an automatic measurement function area, a mathematical operation function area, a bus decoding function area, and a complex analysis function area, etc. Each function area includes a plurality of corresponding function selection controls. The selection controls of the automatic measurement function area include measurement items 1 to 5, which are maximum value, amplitude value, average value, frequency, and overshoot, respectively. The selection controls of the mathematical operation function area include mathematical operations 1 to 5, which are addition, subtraction, multiplication, division, and AND, respectively. The selection controls of the bus decoding function area include buses 1 to 5, which are IIC, SPI, UART, CAN, and LIN, respectively. The selection controls of the complex analysis function area include area screenshot, Bode plot analysis, manual cursor, histogram analysis, power source analysis, Lissajous analysis, and a real-time spectrum. The number and content of the function areas and the selection controls can be set according to requirements. Optionally, the selection control in FIG. 2 includes a checkbox control. It can be understood that the type of the control is set as required and controls with different types can be arbitrarily combined.

S20, obtaining a first control operation via the signal analysis item configuration interface to determine one or more analysis items to be performed. The first control operation of the user is received via a plurality of selection controls in the signal analysis item configuration interface. Optionally, the user performs the first control operation via an input device such as a touch screen, a keyboard, a mouse, voice input, etc. The signal analysis item configuration interface includes a plurality of selection controls to receive the first control operation of the user. Optionally, the selection controls include a plurality of different types to receive different types of first control operations. Referring to FIG. 2, a checkbox control is used to receive a selection control operation on a function area. In a case that a corresponding checkbox control in the function area is selected, it represents that the selection control operation is received. In a case that a checkbox control of histogram analysis in the complex analysis function area is selected, it represents that an analysis item of histogram analysis is received. In a case that a checkbox control in the auto measurement function area is selected and the measurement items 1 and 2 in the function area are selected, it represents that analysis functions of the measurement items 1 and 2 are received. Optionally, after the selection control receives the control operation, a color of the selection control changes. As shown in FIG. 2, the color of the selection control measurement items 1 and 2 changes from white to blue after receiving the control operation. Optionally, the selection controls in FIG. 2 include a checkbox control, and after a certain control is selected, a rectangle box of the control is filled with a color.

The analysis items include a single-channel analysis item, a dual-channel interaction analysis item, and/or a multi-channel interaction analysis item. Optionally, the single-channel analysis item, the dual-channel interaction analysis item, and/or the multi-channel interaction analysis item are displayed on the signal analysis item configuration interface as needed. A single-channel function is a function that can be implemented by performing analysis or parameter measurement on a single-channel signal. A dual-channel or multi-channel interaction function is a function that can be implemented by performing interaction between two or more channel signals. For a time-domain waveform, a single-channel function option includes measurement analysis, cursor analysis, ZOOM amplification, histogram analysis, area decoding, single-channel frequency meter analysis, single-channel digital voltmeter analysis, and Fast Fourier Transform (FFT) operation analysis, etc.

The measurement analysis is used to obtain one or more of following waveform parameters of a selected channel signal in a range of the entire image display area or the selection area: period, frequency, rise time, fall time, positive pulse width, negative pulse width, positive duty cycle, negative duty cycle, the number of positive pulses, the number of negative pulses, the number of rising edges, the number of falling edges, maximum value time, minimum value time, positive slope, negative slope, maximum amplitude value, minimum amplitude value, peak-to-peak value, top value, bottom value, average value, effective value, etc. Exemplarily, the range of the entire image display area is: −800 ns≤t≤1500 ns.

The cursor measurement is used to obtain following parameters of the selected channel signal and a selected waveform range: peak-to-peak value, period, frequency, time range, etc. Exemplarily, the selected waveform range may be: −500 ns≤t≤500 ns, −300 mV≤a≤200 mV.

The ZOOM amplification is used to amplify the selected channel signal and the selected waveform range within the entire image display area or to automatically amplify the selected channel to display the waveform on the screen clearly. The histogram analysis is used to count the number of times that an instantaneous amplitude of each sample value of the waveform occurs in order to understand the structure of the waveform. The histogram is rotated, so that an amplitude scale thereof is vertical to match the waveform, and then superimposed on the signal waveform. The area decoding is used to translate a selected protocol message signal into a corresponding data meaning. The FFT operation analysis is used to perform Fast Fourier Transform on the selected signal to obtain frequency domain information.

The dual-channel interaction analysis item and/or the multi-channel interaction analysis item include: math operation, dual-channel measurement, Lissajous curve, power quality analysis, multi-channel trigger configuration or decoding configuration, etc. The dual-channel measurement is used to obtain information of the two selected channels, such as waveform delay and phase, etc. The math operation is used to perform arithmetic or logical operation on waveforms of the two selected channels. The arithmetic operation includes addition, multiplication, division, and subtraction. The logic operation includes AND, OR, and NOT operations. Lissajous curve is used to obtain a synthetic trajectory of two sinusoidal vibrations in mutually perpendicular directions, and to measure a frequency ratio and phase difference of two signals. The power quality analysis is used to analyze power quality according to a selected channel, for example, using a channel CH1 as voltage and a channel CH3 as current, a selected waveform range can be analyzed, and waveform data of the entire image display area can also be analyzed. The multi-channel trigger configuration or decoding configuration is used to configure the trigger signal. For example, when configuring IIC (I2C) protocol trigger or decoding, the channel CH1 is used as a trigger clock and the channel CH3 is used as data.

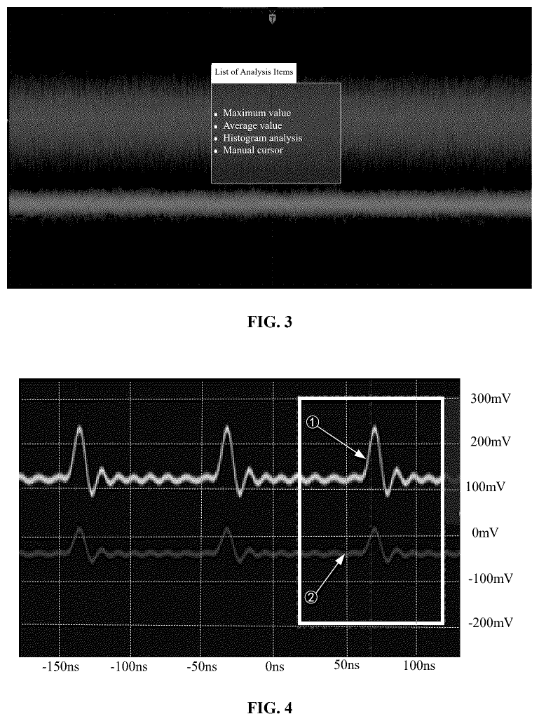

As shown in FIG. 4, two channels CH1 and CH3 and two waveforms \textcircled{1} and \textcircled{2} are selected in the selection area. A rectangular box in the figure is an identification of the selection area drawn by the user. The dual-channel interaction analysis item is the analysis performed on the waveforms of the selected channels CH1 and CH3, for example, addition operation of CH1 and CH3, phase measurement of CH1 and CH3, delay measurement of CH1 and CH3, Lissajous curve analysis of CH1 and CH3, power quality of CH1 and CH3, and trigger of CH1 and CH3, etc.

For the frequency domain waveform, the single-channel function option includes amplification, area peak, signal-to-noise ratio (SNR), bandwidth, and power measurement, etc. The dual-channel or multi-channel interaction analysis item includes math operation, normalization, mutual replication, etc. Optionally, the math operation includes operations such as addition, subtraction, multiplication, division, logarithm, exponentiation, etc.

Optionally, after step S20, the method further includes step S21 of displaying a list of the analysis items to be performed. After the analysis items to be performed are determined, the list of the determined analysis items to be performed is displayed on the screen to show the user the analysis items he/she has selected for easy checking and verifying. As shown in FIG. 3, the list of the analysis items to be performed displayed on the screen includes maximum value, average value, histogram analysis, and manual cursor.

S30, displaying a waveform image of at least one signal in the image display area of the screen according to the at least one obtained signal. The signal to be analyzed is obtained before a waveform of the signal is displayed. The signal may be from more than one channel. Optionally, each channel includes one signal waveform. Optionally, the waveform includes a time domain waveform or a frequency domain waveform. Optionally, step S30 is before or after step S10.

Various types of display screens capable of displaying images is used as the image display area. The display screens include a CRT display screen, a liquid crystal display screen, an LED display screen, an LCD display screen, a touch display screen, etc. The image display area includes a plurality of pixel points. The image is displayed by changing color and brightness of the pixel points. The image is a two-dimensional image or a three-dimensional image. Each pixel point includes a coordinate position and an attribute value of the pixel point. For the two-dimensional image, the coordinate position includes a horizontal coordinate (abscissa) and a vertical coordinate (ordinate). For the three-dimensional image, the coordinate position is represented by three values (x, y, z), where x, y, and z are coordinate values of the x-axis, y-axis, and z-axis, respectively, which have a common coordinate origin and are orthogonal to each other.

The physical meaning represented by the coordinate position varies depending on a measurement device or an object being measured. Optionally, in a two-dimensional image, the coordinate position includes a horizontal coordinate and a vertical coordinate. For example, for an oscilloscope, the horizontal coordinate represents time, and the vertical coordinate represents the signal amplitude (V/mV), such as an amplitude of voltage or current; for a spectrum analyzer, the horizontal coordinate represents frequency, and the vertical coordinate represents signal power in decibels (dB). In a three-dimensional image, x represents time or frequency, y represents amplitude or power, and z represents waveform number or channel number.

Color attributes of different pixel points are used to represent different waveforms in a waveform image. Optionally, a color value adopts different color modes such as a RGB color mode, a HSB color mode, a grayscale mode, a bitmap mode, etc. In the RGB color mode, a color is composed of three primary colors: red (R), green (G), and blue (B). In the HSB color mode, a color is represented by hue (H), saturation (S), and brightness (B). The grayscale mode uses different gray levels to represent brightness, such as 0˜255. The bitmap mode uses black and white colors to represent pixels in the image.

Optionally, signal data is read from a storage unit, and the signal data to be processed is stored in the storage unit in advance, or the signal data is obtained by processing signals collected from an input port in real time. Exemplarily, a method for obtaining the signal data is as follows: firstly, a probe is used to sample the signal to obtain an analog input signal; then, an analog signal processing unit is used to control the analog input signal to be gained, offset, and amplified or attenuated, thereby outputting a signal with a suitable amplitude; subsequently, an analog-to-digital conversion is performed on the signal output by the analog signal processing unit, and the converted digital signal is output; and subsequently, the digital signal is collected and cached in the storage unit. The signals collected a plurality of times are overlapped, performed data processing, such as compression, filtering, interpolation, or the like, and then stored to obtain waveform data. Optionally, the signals of different analog signal processing units are identified with different colors.

The waveform image includes a waveform portion and a background portion. FIG. 4 shows a partial image display area of a display screen, where the horizontal axis represents time in nanoseconds (ns), and the vertical axis represents amplitude in millivolts (mV). Two waveform images \textcircled{1} and \textcircled{2} are displayed in the image display area. The color of waveform \textcircled{1} is yellow, and represented by a first pixel value; the color of waveform \textcircled{2} is red, and represented by a second pixel value. Background in the image display area is black and represented by a third pixel value.

It can be understood that the number of waveforms displayed in the image display area is not limited, and may be two as shown in FIG. 4, or may be one, three, five, etc. The type of the displayed waveform is also not limited and may be a rectangular wave, a triangle wave, a sine wave, or any other type of waveform.

S40, displaying a selection area in the image display area of the screen in response to a second control operation, where the selection area is configured to indicate an area selected through the second control operation in the image display area. The user draws the selection area or selects a certain area in the image display area through the second control operation. The selection area includes the waveform image of the signal to be analyzed selected through the second control operation, for example, the waveform image of a certain channel or several channels. The user can select a waveform desired to be analyzed through the second control operation.

The selection area may be a closed area or a non-closed area. An identification of the selection area may be a regular shape, such as a rectangle, a circle, a triangle, an ellipse, etc., referring to FIG. 6, or may be an irregular shape, such as a hand-drawn circle, or a shape of a certain area enclosed by a plurality of line segments or arcs. By displaying the selection area in the image display area, it is convenient for the user to determine whether the current selection area is a desired selection area in a manner of What You See Is What You Get. The selection area may be one, or two or more. FIG. 6 illustrates three selection areas. The implementation of the second control operation may include a keyboard, a mouse, a microphone, a gesture recognition device, a touch display screen or a touchpad, etc., which is not limited in the present disclosure. In this way, the user can intuitively and flexibly select the waveform to be analyzed.

Optionally, the selection area is obtained by changing an icon position of the image display area. The icon is used to track in real time a change of a contact position where the image display area is contacted, or a position of a pixel point selected in the image display area. Optionally, when the image display area is contacted by a finger or a stylus to draw the selection area, the icon can track the change of a position of the finger or stylus on the image display area, such as a movement trajectory. Alternatively, when the pixel point is selected by the mouse and a cursor of the mouse is moved in the image display area, the icon can display the change of the position of the selected pixel point. The icon may be a pattern such as an arrow, a circle, a cross, etc., with a certain color.

It can be understood that when the mouse cursor moves in the image display area, or the finger or stylus contacts the image display area and moves in the image display area, the icon will change into a line as the mouse cursor, finger or stylus moves, so as to track the position change or movement trajectory thereof, thereby forming the identification of the selection area.

Optionally, a method for drawing the selection area is as follows: selecting two pixel points in the image display area; displaying positions of the two pixel points by icons; using coordinate values of the two pixel points as diagonal vertices of a rectangle, where four sides of the rectangle are parallel to the horizontal coordinate and the vertical coordinate; and determining an area defined by the rectangle as the selection area. Alternatively, a plurality of pixel points are selected in the image display area, the selected pixel points are connected in sequence, and an area enclosed by the sequentially connected pixel points are determined as the selection area. An image range of the selection area are determined by obtaining coordinates of the pixel points identified in the selection area.

The selection of the pixel points is achieved by operating an input device such as a mouse, a touch screen, or a touchpad, etc. Optionally, the operation method is as follows: clicking the mouse button or clicking the touch screen or the touchpad a plurality of times, and a position of the icon in the image display area at each click is the position of the selected pixel point. Alternatively, firstly press the mouse button, or press the touch screen or the touchpad with a finger or a stylus, then drag the mouse, the finger, or the stylus in a predetermined trajectory, and positions where the icon passes are positions of the selected pixel points. Alternatively, firstly press the mouse button, or press the touch screen or the touchpad with a finger or a stylus, then drag the mouse, the finger, or the stylus in a predetermined trajectory, then release the button, the finger, or the stylus, and positions of the icon when the mouse button is pressed and released are the positions of the selected pixel points.

Through the above visual operation method, the waveform to be analyzed can be selected flexibly and conveniently, thereby simplifying the operation of the signal analysis instrument and improving the efficiency of signal analysis.

S50, obtaining a parameter of the signal selected through the second control operation according to an image in the selection area. The parameter of the signal includes a channel list of the signal. The parameter of the signal may also include a first signal range and a second signal range. The selection area drawn or defined by the user in the image display area through the second control operation includes a waveform image of the signal desired to be analyzed. According to the waveform image in the selection area, the channel list of the signal selected through the second control operation is determined. Optionally, the channel list includes information such as the number of channels and/or channel identifications, etc. The channel identification is configured to represent a channel to which the waveform belongs. Optionally, the channel list is determined by counting color values of image pixels in the selection area. Each channel corresponds to a different color, so that the waveform image can be displayed differently. Therefore, by determining the pixel color values of an image in the selection area, the number of channels, channel identifications, and other information can be determined. Specifically, the following steps are included:

S501, obtaining the pixel colors of the image in the selection area. Image data in the selection area includes a horizontal coordinate, a vertical coordinate, and the pixel color value of each pixel point in the selection area. Since each channel corresponds to a different color value, the number and identifications of the channels can be determined according to the color values. In FIG. 4, a horizontal coordinate range of a selection area defined by a white solid line box is (0 ns, 150 ns), and a vertical coordinate range of the selection area is [−200 mV, 300 mV]. The selection area includes three colors, yellow and red represent waveform images \textcircled{1} and \textcircled{2}, respectively, and black represents the background. Three codes #FFDD55, #FF3333, and #000000 are used to represent the above three colors, respectively. Pixel color values in the selection area are counted, and color values of non-background are obtained as #FFDD55 and #FF3333.

S502, determining the channel list according to a correspondence between the pixel colors and channels of signals. When the waveform data is displayed as an image, the waveform of each channel is represented by a different pixel color value. After the obtained pixel color values in the selection area are counted, the channel list selected in the selection area is determined according to the correspondence between the pixel color values and the channels of the signals. The channel list includes information such as the number of the channels, channel identifications, and gear positions, etc. In FIG. 4, the color values of the waveform images \textcircled{1} and \textcircled{2} are #FFDD55 and #FF3333, respectively, the types of pixel colors in the selection area are two, and the corresponding channel identifications are CH1 and CH3, respectively.

Optionally, the step S501 also includes S5011, selecting at least one column of pixels in the selection area, and determining the pixel colors of the image in the selection area according to colors of the at least one column of pixels. Color types of the at least one column of pixels are counted as the types of the pixel colors of the image in the selection area. The image data are stored in a two-dimensional array, a column index of the array corresponds to the horizontal coordinate of the image, a row index of the array corresponds to the vertical coordinate of the image, and a value of the array corresponds to the pixel color value at the coordinate position. Optionally, a column where a longitudinal symmetry axis of the selection area locates is selected to be counted. By selecting only one column in the selection area to be counted, counting operations on all pixels in the selection area is avoided, and thus the operation speed is improved.

Optionally, the parameter of the signal further includes a first signal range, a second signal range, and signal data. For a time domain waveform, the first signal range and the second signal range are a time range and an amplitude range, respectively. For a frequency domain waveform, the first signal range and the second signal range are a frequency range and a signal power range, respectively.

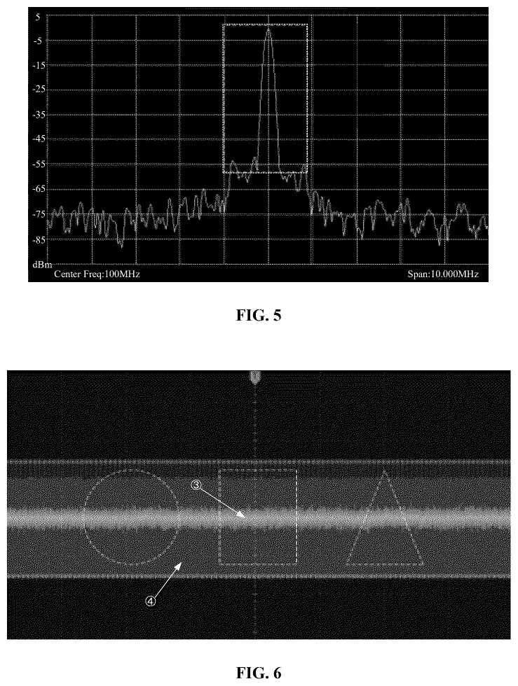

S511, determining the first signal range and the second signal range according to a horizontal range and a vertical range of the image in the selection area. The horizontal coordinate and the vertical coordinate of the waveform image represent different physical meanings. For the time domain waveform, when the signal data is displayed, the horizontal coordinate of each pixel in the image corresponds to different time of the signal, and the vertical coordinate of each pixel corresponds to the amplitude of the signal. For the frequency domain waveform, when the signal data is displayed, the horizontal coordinate of each pixel in the image corresponds to a different frequency of the signal, and the vertical coordinate of each pixel corresponds to power of the signal. According to the horizontal range of the image in the selection area, a starting time and an ending time, or a starting frequency and an ending frequency of the selected signal to be analyzed, that is, the first signal range, is determined. According to the vertical range of the image in the selection area, an amplitude range or a power range of the selected signal to be analyzed, that is, the second signal range, is determined. As shown in FIG. 4, for a time domain waveform image, the selection area is defined by the white solid line box. According to the above correspondence between the image and the waveform, the first signal range is obtained: time t, 0 ns<t<150 ns, and the second signal range is obtained: amplitude a, −200 mV≤a≤300 mV. For a frequency domain waveform image, as shown in FIG. 5, the selection area is defined by a dotted line box, the first signal range is about 90 MHz˜110 MHz, and the second signal range is about −58 dBm˜2 dBm.

For some analysis items, only the first signal range and the second signal range need to be obtained to perform, for example, ZOOM amplification.

Optionally, the channel list is determined by comparing data ranges of the signals.

S512, determining the channel list according to the first signal range and the second signal range. The time and amplitude of each channel signal data are compared from the obtained signals to determine whether the channel signal data fall within the selected data range. If yes, it indicates that the channel signal is selected. Firstly, a signal corresponding to the data in the first signal range is found in the obtained data collected by each channel. Then, a signal channel corresponding to the data within the first signal range and the second signal range is determined. As shown in FIG. 4, a signal data range of the selection area is as follows: time t, 0 ns<t<150 ns; and amplitude a, −200 mV≤a≤300 mV. By comparing the obtained signal data, it can be seen that signals of two channels CH1 and CH3 fall within the signal data range of the selection area, then it can be determined that the channels selected in the selection area are the two channels CH1 and CH3.

When the waveform images overlap, the channel list cannot be determined by the image pixel colors. As shown in FIG. 6, waveforms \textcircled{3} and \textcircled{4} of the two channels CH1 and CH3 overlap. At this time, the channel list may be determined by comparing the channel signal data, thereby effectively solving the problem of the overlapping of the waveform images.

S60, performing the one or more analysis items to be performed according to the parameter of the signal, and displaying the performing result. After the selection area is determined through the second control operation, the parameter of the signal in the selection area is automatically read, the determined analysis item to be performed is started and performed. Each function module of an instrument is called to perform the determined function to be performed. Different parameters of the signal are selected to be transmitted according to different functions to be performed. Optionally, if a function option determined through the second control operation is an FFT operation, data and a horizontal range, for example, [−100 ns, 100 ns], of the selected channel are transmitted. If the function option determined through the second control operation is cursor analysis, the data, the horizontal range, for example, [−500 ns, 500 ns], and a vertical range, for example, [−200 mV, 300 m V], of the selected channel are transmitted. If the function option determined through the second control operation is ZOOM amplification, the horizontal range, for example, [−500 ns, 500 ns], of a display area in the screen is transmitted.

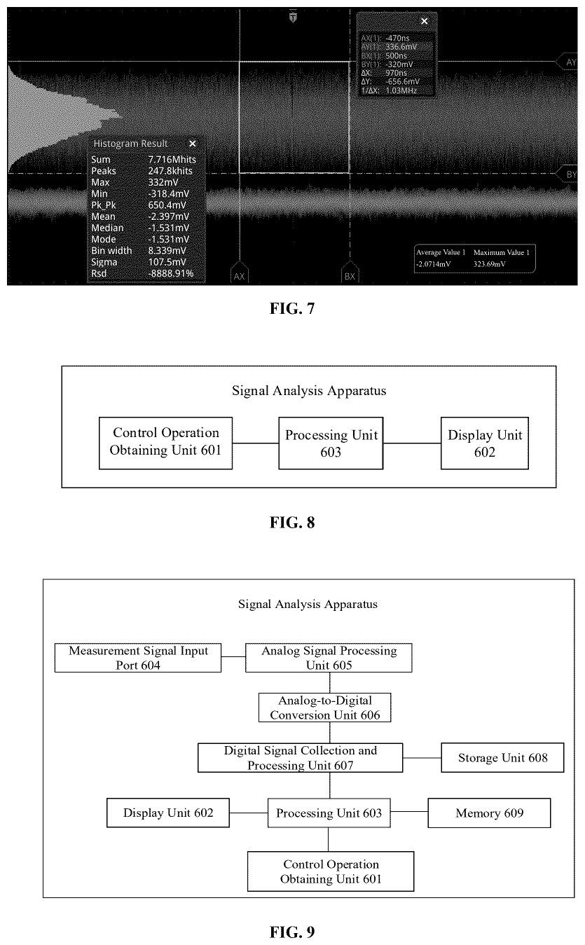

Optionally, an analysis result is displayed in the image display area. Referring to FIG. 7, the image display area simultaneously displays the image of the signal waveform and the analysis result. A solid-line rectangular box in the figure is the selection area. A lower left part in the figure is the histogram analysis result, an upper right part is the analysis result of the manual cursor, and a lower right part is the analysis result of the average value and the maximum value. The number of the display areas of the performing result is determined according to the number of the analysis items to be performed.

The first control operation is obtained via the signal analysis item configuration interface, so as to set the item desired to be analyzed, and the second control operation is obtained, so as to determine the selected signal waveform to be analyzed in the image display area of the screen, thereby implementing that the analysis items concerned by the user can be freely configured, and the signal to be analyzed can be quickly selected. In this way, the technical problem of the signal analysis traditionally realized by performing a plurality of interactions, which is complicated, time-consuming, and inefficient, can be solved, thereby improving operational flexibility and convenience of the waveform analysis, and improving efficiency of the signal analysis.

Another embodiment of the present disclosure provides a signal analysis apparatus configured to implement the above-mentioned signal analysis interaction method. Optionally, referring to FIGS. 8 and 9, the signal analysis apparatus includes:
a control operation obtaining unit 601, configured to obtain a first control operation via a signal analysis item configuration interface to determine one or more analysis items to be performed;
a display unit 602, configured to display the signal analysis item configuration interface in a screen. The display unit 602 is also configured to display a waveform image of at least one obtained signal in an image display area of the screen according to the at least one obtained signal. Optionally, the display unit 602 is further configured to display an identification of a selection area, a selection control, and/or a signal performing result. Optionally, the performing result is a result corresponding to a certain function option or several function options. The screen is also included in the signal analysis apparatus.

The control operation obtaining unit 601 is further configured to obtain a second control operation for selecting a signal waveform to be analyzed. The display unit 602 displays the selection area in the image display area of the screen in response to the second control operation. The selection area is configured to indicate an area selected through the second control operation in the image display area.
a processing unit 603, configured to obtain a parameter of the signal selected through the second control operation according to an image in the selection area. The processing unit 603 is further configured to perform the analysis item to be performed according to the parameter of the signal and control the display unit to display the performing result. The processing unit 602 can also be referred to as a processor.

In an optional embodiment, the step of displaying the function option to be performed according to the channel list includes: determining the number of channels in the channel list, and in response to that the number of channels is 1, displaying a first function option; and in response to that the number of channels is greater than or equal to 2, displaying a second function option.

In an optional embodiment, the parameter of the signal includes a channel list of the signal. The channel list is determined according to a correspondence between pixel colors and channels of the signal.

In an optional embodiment, the step of obtaining the pixel colors of the image in the selection area includes selecting at least one column of pixels in the selection area; and determining the pixel colors of the image in the selection area according to colors of the at least one column of pixels.

In an optional embodiment, the parameter of the signal includes a first signal range and a second signal range. The step of obtaining the parameter of the signal selected through the second control operation according to the image in the selection area includes determining the first signal range and the second signal range, respectively, according to a horizontal range and a vertical range of the image in the selection area.

In an optional embodiment, the parameter of the signal includes a channel list of the signal. The channel list is determined according to the first signal range and the second signal range.

In an optional embodiment, after the step of obtaining the first control operation via the signal analysis item configuration interface to determine the one or more analysis items to be performed, the method further includes displaying a list of the analysis items to be performed.

In an optional embodiment, the waveform of the at least one signal includes a time domain waveform or a frequency domain waveform. A parameter of the signal corresponding to the time domain waveform includes a time range, an amplitude range, a channel identification, and/or signal data. A parameter of the signal corresponding to the frequency domain waveform includes a frequency range, a signal power, a channel identification, and/or signal data.

In an optional embodiment, the signal analysis apparatus further includes a measurement signal input port 604 configured to receive a measurement signal.

In an optional embodiment, the signal analysis apparatus further includes an analog signal processing unit 605 configured to control the gain and offset of the analog signal input, amplify or attenuate the analog signal, thereby generating a signal with a suitable amplitude, and outputting the signal to an analog-to-digital conversion unit.

In an optional embodiment, the signal analysis apparatus further includes an analog-to-digital conversion unit 606 configured to receive the signal from an analog front end and convert the signal into a digital signal.

In an optional embodiment, the signal analysis apparatus further includes a digital signal collection and processing unit 607 configured to collect and cache the digital signal to a storage unit, overlap signals collected a plurality of times, and perform data processing, such as compression, filtering, or interpolation, etc., to obtain waveform data. Different analog front-end signals are identified with different colors.

In an optional embodiment, the signal analysis apparatus further includes a storage unit 608 configured to store the waveform data output by the digital signal collection and processing unit.

In an optional embodiment, the signal analysis apparatus further includes a memory 609 configured to store an application program and cache data of a display screen.

Specific limitations of the signal analysis apparatus can refer to the limitation regarding the above-mentioned signal analysis interaction method, which is not repeated herein. Each module in the above-mentioned signal analysis interaction method may be implemented in whole or in part by software, hardware, or a combination thereof. Each of the above-mentioned modules may be embedded in or independent from a processor in a computer device in the form of hardware, or may be stored in the memory of the computer device in the form of software, so that the processor may call and execute operations corresponding to each of the above-mentioned modules.

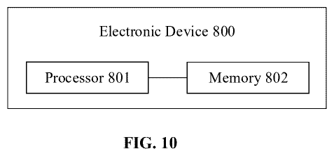

An embodiment of the present disclosure also provides an electronic device. FIG. 10 is a schematic structural diagram illustrating an electronic device provided in an embodiment of the present disclosure. As shown in the figure, the electronic device 800 includes one or more processors 801 and a memory 802. Computer-executable instructions are stored in the memory 802. The processor 801 is configured to execute the computer-executable instructions to implement the steps of the signal analysis interaction method in any of the above embodiments. The processor 801 may be a Central Processing Unit (CPU) or other forms of processing units with data processing capability and/or instruction execution capability, and may control other components in the electronic device to perform desired functions.

The memory 802 may include one or more computer program products, and the computer program products may include various forms of computer-readable storage media, such as a volatile memory and/or a non-volatile memory. The volatile memory may include, for example, a Random Access Memory (RAM) and/or a cache, etc. The non-volatile memory may include, for example, a Read-Only Memory (ROM), a hard disk, a flash memory, etc. One or more computer program instructions may be stored on the computer-readable storage media, and the processor 801 may run the program instructions to implement the steps and/or other desired functions in the signal analysis interaction method in each embodiment of the present disclosure described above.

In one example, the electronic device 800 may also include an input apparatus and an output apparatus, and these components may be interconnected through a bus system and/or a connection mechanism in other forms (not shown in figures). In addition, the input apparatus may also include, for example, a keyboard, a mouse, a microphone, etc. The output apparatus may output various information to outside, for example, it may include, for example, a display, a speaker, a printer, a communication network, and a remote output device connected thereto, etc. Certainly, for simplicity, only a part of the components related to the present disclosure in the electronic device 800 are shown in FIG. 10, and components such as a bus, an input apparatus/output interface, etc. may be omitted. In addition, according to specific application situation, the electronic device 800 may also include any other appropriate components. In one embodiment, a computer-readable storage medium is provided, on which a computer program is stored, and when the computer program is executed by a processor, the steps of the above-mentioned signal analysis interaction method are implemented.

Those skilled in the art can understand that all or part of the processes to implement the methods in the above-mentioned embodiments may be completed by instructing a relevant hardware through a computer program, and the computer program may be stored in a non-volatile computer-readable storage medium, and when the computer program is executed, it can include the processes in the embodiment of each of the above-mentioned methods. Any reference to a memory, a storage, a database or other media used in each embodiment provided in the present disclosure may include at least one of a non-volatile memory and a volatile memory. The non-volatile memory may include a Read-Only Memory (ROM), a tape, a floppy disk, a flash memory, an optical memory, etc. The volatile memory may include a Random Access Memory (RAM) or an external cache. As illustration and not a limitation, RAM may be in various forms, such as a Static Random Access Memory (SRAM), or a Dynamic Random Access Memory (DRAM), etc.

Various technical features of the above embodiments may be combined arbitrarily. To simplify the description, not all possible combinations of various technical features in the above-mentioned embodiments are described. However, as long as there is no conflict in the combinations of these technical features, all should be considered to be within the scope described in the specification.

The above-described embodiments only express several implementations of the present disclosure, and the descriptions thereof are relatively specific and detailed, but they should not be understood as limiting the scope of the present disclosure. It should be noted that, for those skilled in the art, various modifications and improvements can be made without departing from the concept of the present disclosure, and these all fall within the protection scope of the present disclosure. Therefore, the protection scope of the present disclosure should be subject to the appended claims.

1. A signal analysis interaction method, applied to a signal analysis apparatus comprising a screen, the method comprising:
displaying a signal analysis item configuration interface in the screen;
obtaining a first control operation via the signal analysis item configuration interface to determine one or more analysis items to be performed;
displaying a waveform image of at least one obtained signal in an image display area of the screen according to the at least one obtained signal;
displaying a selection area in the image display area of the screen in response to a second control operation, wherein the selection area is configured to indicate an area selected through the second control operation in the image display area;
obtaining a parameter of the signal selected through the second control operation according to an image in the selection area; and
performing the one or more analysis items to be performed according to the parameter of the signal and displaying a performing result.

2. The signal analysis interaction method of claim 1, wherein the parameter of the signal comprises a channel list of the signal, and
the step of obtaining a parameter of the signal selected through the second control operation according to an image in the selection area comprises:
obtaining pixel colors of the image in the selection area; and
determining the channel list according to a correspondence between the pixel colors and channels of the signal.

3. The signal analysis interaction method of claim 2, wherein the step of obtaining pixel colors of the image in the selection area comprises:
selecting at least one column of pixels in the selection area; and
determining the pixel colors of the image in the selection area according to colors of the at least one column of pixels.

4. The signal analysis interaction method of claim 1, wherein the parameter of the signal comprises a first signal range and a second signal range, and the step of obtaining a parameter of the signal selected through the second control operation according to an image in the selection area comprises:
determining the first signal range and the second signal range, respectively, according to a horizontal range and a vertical range of the image in the selection area.

5. The signal analysis interaction method of claim 4, wherein the parameter of the signal comprises a channel list of the signal, and the method comprises:
determining the channel list according to the first signal range and the second signal range.

6. The signal analysis interaction method of claim 1, wherein after the step of obtaining a first control operation via the signal analysis item configuration interface to determine one or more analysis items to be performed, the method further comprises:
displaying a list of the analysis items to be performed.

7. The signal analysis interaction method of claim 1, wherein a waveform of the at least one obtained signal comprises a time domain waveform or a frequency domain waveform,
the parameter of the signal corresponding to the time domain waveform comprises a time range, an amplitude range, a channel identification, and/or signal data, and
the parameter of the signal corresponding to the frequency domain waveform comprises a frequency range, a signal power, a channel identification, and/or signal data.

8. A signal analysis apparatus, comprising:
a screen comprising an image display area, wherein a signal analysis item configuration interface is displayed in the screen, a waveform image of at least one obtained signal in the image display area according to the at least one obtained signal, and a selection area is displayed in the image display area in response to an obtained second control operation, and configured to indicate an area selected through the second control operation in the image display area;
a processor, configured to obtain a parameter of the signal selected through the second control operation according to an image in the selection area, perform one or more analysis items to be performed according to the parameter of the signal, and control the display of a performing result, wherein the one or more analysis items to be performed are determined according to a first control operation obtained via the signal analysis item configuration interface.

9. An electronic device, comprising a memory and a processor, a computer program being stored in the memory, wherein the processor is configured to execute the computer program to implement a signal analysis interaction method, wherein the signal analysis interaction method comprises:
displaying a signal analysis item configuration interface in a screen;
obtaining a first control operation via the signal analysis item configuration interface to determine one or more analysis items to be performed;
displaying a waveform image of at least one obtained signal in an image display area of the screen according to the at least one obtained signal;
displaying a selection area in the image display area of the screen in response to a second control operation, wherein the selection area is configured to indicate an area selected through the second control operation in the image display area;
obtaining a parameter of the signal selected through the second control operation according to an image in the selection area; and
performing the one or more analysis items to be performed according to the parameter of the signal and displaying a performing result.

10. A computer readable storage medium, having a computer program stored thereon, wherein when the computer program is executed by a processor, steps of the signal analysis interaction method according to claim 1 are implemented.

11. The electronic device according to claim 9, wherein the parameter of the signal comprises a channel list of the signal, and the processor is configured to obtain pixel colors of the image in the selection area, and determine the channel list according to a correspondence between the pixel colors and channels of the signal.

12. The electronic device according to claim 11, wherein the processor is configured to select at least one column of pixels in the selection area, and determine the pixel colors of the image in the selection area according to colors of the at least one column of pixels.

13. The electronic device according to claim 9, wherein the parameter of the signal comprises a first signal range and a second signal range, and the processor is configured to determine the first signal range and the second signal range, respectively, according to a horizontal range and a vertical range of the image in the selection area.

14. The electronic device according to claim 11, wherein the parameter of the signal comprises a channel list of the signal, and the processor is configured to determine the channel list according to the first signal range and the second signal range.

15. The electronic device according to claim 9, wherein the processor is configured to display a list of the analysis items to be performed.
